(19) United States
(12) Patent Application Publication
(10) Pub. No.: US 2007/0253798 A1
(43) Pub. Date: Nov. 1, 2007

(54) Apparatus for opening/closing cover of thin-film disc containing cassette

(76) Inventor: Kyung Baik Jo, Fremont, CA (US)

Correspondence Address: ROSENBERG, KLEIN & LEE, 3458 ELLICOTT CENTER DRIVE-SUITE 101, ELLICOTT CITY, MD, 21043, US

(21) Appl. No.: 11/443,188

(22) Filed: May 31, 2006

(30) Foreign Application Priority Data
Apr. 27, 2006 (KR) 10-2006-0038364

(51) Int. Cl. H01L 21/677

(52) U.S. Cl. 414/217; 414/411

(57) ABSTRACT

Disclosed is apparatus for opening/closing a cover of a thin-film disc containing cassette. The thin-film disc containing cassette cover opening/closing apparatus includes: a main conveyer for feeding and conveying a cassette, in which plural thin-film discs are contained; top opening/closing member positioned above the main conveyer so as to open/close a top cover of the cassette; an elevator for inducing vertical movement of the top opening/closing member; a bottom opening/closing member positioned below the main conveyer so as to open/close a bottom cover of the cassette; a conveyer regulating member for regulating the width of the main conveyer according to the size of the cassette, the main conveyer being supported on the conveyer regulating member; and a cassette anchoring member for supporting and anchoring the cassette transferred to a main body of the apparatus through the main conveyer.

### BACKGROUND OF THE INVENTION

1. Field of the invention

The present invention relates to an apparatus for opening/closing a cover of a thin-film disc containing cassette (for the convenience of description, hereinafter, the apparatus may be also referred to as “thin-film disc containing cassette cover opening/closing apparatus,” “cassette cover opening/closing apparatus or “cover opening/closing apparatus”), and more particularly to a thin-film disc containing cassette cover opening/closing apparatus, which is capable of safely opening/closing top and bottom covers of a thin film disc containing cassette, in which plural thin-film discs are contained, without producing dust before and after a process for testing the thin-film discs contained in the cassette, so that the thin-film discs can be retained under a super clean condition within a clean room.

2. Description of the Prior Art

As well-known in the art, thin-film discs are fed into a predetermined process in a state in which plural thin-film discs are contained in one cassette. Such a thin-film disc containing cassette for containing plural thin-film discs like this typically has covers, which are put on the top and bottom of the cassette, respectively; in the prior art, those covers have been opened/closed by a cassette cover opening/closing apparatus before and after a test process, wherein the cover opening/closing apparatus mainly employs an air cylinder so as to open/close the covers. In general, however, such an apparatus employing an air cylinder cannot be used in a super clean room, of which the cleanliness level is at least “class 10,” because the high-pressure air used by the air cylinder may contaminate the entirety of the clean room if it escapes from the air cylinder through a minute defect, which may exist in the air cylinder, while the air cylinder is operating in the clean room. Because the leakage of high-pressure air causes contamination over a very wide area, it takes much time and expense to restore the clean room to its original condition.

With such a cassette cover opening/closing apparatus employing an air cylinder, it is not easy to control the air pressure. Due to this, it is impossible to freely adjust the operating velocity and distance for opening/closing the covers of a cassette, and it is also impossible to properly cope with various changes in working condition.

Accordingly, the use of high-pressure air within a super clean room has been limited recently, and in opening/closing the covers of a cassette containing plural thin-film discs, an operator has no choice but to manually open/close the covers of the cassette with his or her hands on the spot, instead of opening/closing the covers using an air cylinder as in the prior art.

In particular, a contaminant, such as dust, which is produced in the course of opening/closing the covers of a cassette, may contaminate a test space, which requires high cleanliness, as well as thin-film discs before and after the test, which will result in considerable loss of time and expense for normalizing the test space.

### SUMMARY OF THE INVENTION

Accordingly, the present invention has been made to solve the above-mentioned problems occurring in the prior art, and an object of the present invention is to provide a thin-film disc containing cassette cover opening/closing apparatus, which is capable of safely opening/closing top and bottom covers of a cassette for containing plural thin-film discs during the process of fabricating thin-film discs without producing dust.

Another object of the present invention is to provide a thin-film cassette cover opening/closing apparatus, which allows the cassette cover opening/closing operation to be more smoothly performed without requiring a complete change in the apparatus even if the sizes of individual cassettes fed into a predetermined process are varied because each working unit is capable of being flexibly operated in accordance with the sizes of the cassettes.

In order to achieve above-mentioned objects, there is provided an apparatus for opening/closing a cover of a thin-film disc containing cassette comprising: a main conveyer for feeding and conveying a cassette, in which plural thin-film discs are contained; top opening/closing means positioned above the main conveyer so as to open/close a top cover of the cassette; an elevator for inducing vertical movement of the top opening/closing means; a bottom opening/closing means positioned below the main conveyer so as to open/close a bottom cover of the cassette; a conveyer regulating means for regulating the width of the main conveyer according to the size of the cassette, the main conveyer being supported on the conveyer regulating means; and a cassette anchoring means for supporting and anchoring the cassette transferred to a main body of the apparatus through the main conveyer.

According to a preferred embodiment, the main conveyer is connected to an inlet conveyer means and an outlet conveyer means, the inlet conveyer means being connected to an inlet side of the main body and the outlet conveyer means being connected to an outlet side of the outlet conveyer means, the conveyer regulating means is interposed between the main conveyer and the bottom opening/closing means, and the cassette anchoring means is interposed between the top opening/closing means and the main conveyer.

The top opening/closing means is fitted and secured to the elevator so that the top opening/closing means is capable of being moved up and down depending on the movement of the elevator; the elevator is installed at the center of the rear side of a main frame, which is the bone structure of the main body, and guides the ascent and descent of the top opening/closing means through a lifting belt, which is driven by a motor. The elevator comprises a moving holder, to which the top opening/closing means is engaged, one or more guide bars for guiding the ascent and descent of the moving holder, a side of which is connected to the lifting belt for such movement.

The top opening/closing means comprises: a body which corresponds to the base unit of the top opening/closing means; wing units, which are hinged to the opposite ends of the body, respectively, in such a manner as to be rotatable in the inward and outward directions, each of the wing units having a gripping means; and a driving unit for controlling the rotating movements of the wing units, wherein the body, the wing units and the driving unit are housed in a single case. The driving unit of the top opening/closing means comprises: a threaded driving shaft which extends downward from a wing regulating motor, which corresponds to a power source for rotating the wing units, an articulated member which is engaged with the driving shaft, and joint arms which connect the opposite sides of the articulated member to the top portions of the wing units, respectively, the opposite ends of each of the joint arms being rotatably hinged to the wing units and the articulated member.

According to the present invention, each of the wing unit comprises: a plate-shaped base member; a lifting motor mounted on the outer upper portion of the base member; a threaded lifting shaft rotatably extending downward from the hook regulating motor; plural extension bars extending from a supporting die, which is fixed to the lower end of the lifting shaft; and a hook adapted to grip the top cover of the thin-film disc containing cassette in a state in which the hook is engaged with and secured to the lower end of the extension bar.

In the above-mentioned top opening/closing means, the rotating directions of the wing units are changed depending on the driving direction of the wing regulating motor, wherein for this rotation, the wing units are hinged to the opposite ends of the body through hinge members, respectively, and the conveyer regulating means is configured in a plate shape, and provided with first and second actuating shafts at the longitudinal ends of the plate, which are interconnected by a linking belt and a driving belt, so that the first and second actuating shafts are actuated in cooperation with a motor.

According to the present invention, the thin-film cassette cover opening/closing apparatus may further comprise one or more air intake means so as to remove a contaminant such as dust which may be produced while the inventive apparatus operates, wherein the air intake means comprises: a first air intake tube, which is installed in the case of the top opening/closing means so as to suction a contaminant produced within the case, a second air intake tube, which is installed in the top opening/closing means so as to suction a contaminant produced from the wing units, the second intake tube having branch tubes, which are connected with the wing units, respectively, and a third air intake tube is installed in the bottom opening/closing means so as to remove a contaminant produced from the bottom opening/closing means, wherein the contaminants, which are produced in various parts of the inventive apparatus and suctioned through the first, second and third air intake tubes, flow along pipes extending from the first, second and third intake tubes, whereby the contaminants are adapted to be discharged to the outside together by the wind, which is blown through a discharge pipe of air discharge means.

With the inventive thin-film disc containing cassette cover opening/closing apparatus, it is possible to open or close the top and bottom covers of a cassette without producing a contaminant in a test process for thin-film discs, thereby assuring the quality and safety of articles. In addition, the inventive thin-film disc containing cassette cover opening/closing apparatus allows the cassette cover opening/closing operation to be more smoothly performed without requiring a complete change in the apparatus even if the sizes of cassettes fed into a predetermined process are varied because each working unit is capable of being flexibly operated in accordance with the sizes of individual cassettes.

### BRIEF DESCRIPTION OF THE DRAWINGS

The above and other objects, features and advantages of the present invention will be more apparent from the following detailed description taken in conjunction with the accompanying drawings, in which:

FIG. 1 is a perspective view showing the entire construction of the inventive thin-film disc containing cassette cover opening/closing apparatus;

FIG. 2 is an exploded perspective view showing the components of a top opening/closing means and connective relationship between them in an enlarged scale;

FIG. 3 is a perspective view showing the components of an elevator for raising and lowering the top opening/closing means of FIG. 2 and the connective relationship between them;

FIG. 4 is an exploded perspective view showing the components of a bottom opening/closing means and a conveyer regulating means and the connective relationship between;

FIG. 5 is an exploded perspective view showing the components of a cassette anchoring means, which is installed within the main body of FIG. 1;

FIG. 6 is a schematic view showing inlet conveyer means and outlet conveyer means which are connected to the inlet and outlet of the inventive cassette cover opening/closing apparatus, respectively;

FIG. 7 is an schematic view showing the components of a thin-film disc containing cassette of FIG. 6;

FIGS. 8 to 14 show the process for opening the top and bottom covers in sequence while the cassette containing plural thin-film discs is passing through the inventive apparatus;

FIG. 15 shows the main conveyer which has been displaced by the conveyer regulating means of FIG. 4 before the process of opening the cassette covers as shown in FIGS. 8 to 14;

FIG. 16 shows the main conveyer which has been displaced again by the conveyer regulating means of FIG. 4 during the process of closing the cassette covers, which is performed in a reversed order with reference to the process of opening the cassette covers shown in FIG. 8 to 14; and

FIG. 17 shows schematic arrangement of air intake means installed to various parts of the inventive cassette cover opening/closing apparatus and acting relationship thereof.

### DETAILED DESCRIPTION OF THE PREFERRED EMBODIMENTS

Hereinafter, a preferred embodiment of the present invention will be described with reference to the accompanying drawings. In the following description and drawings, the same reference numerals are used to designate the same or similar components, so that repeated description on the same or similar components will be omitted.

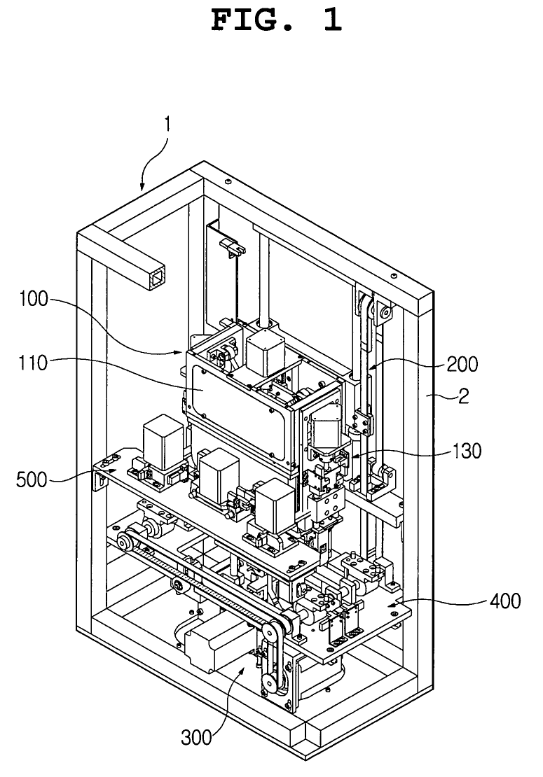

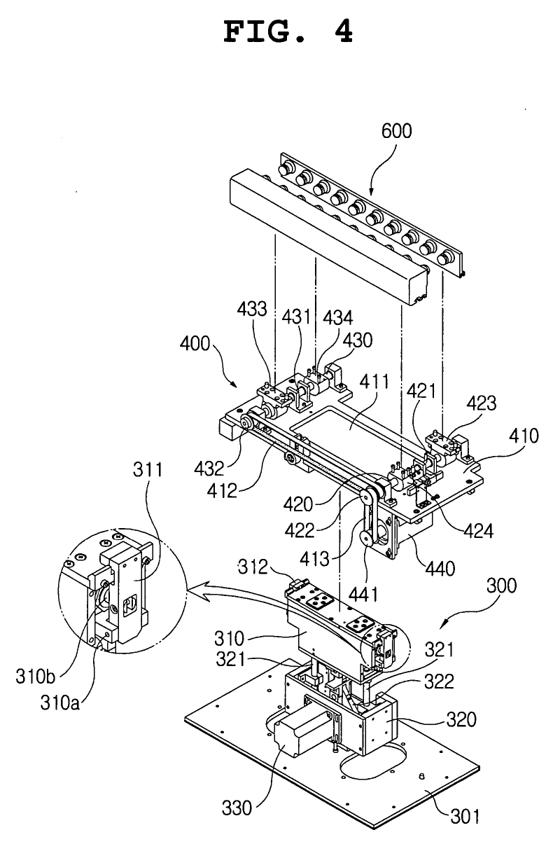

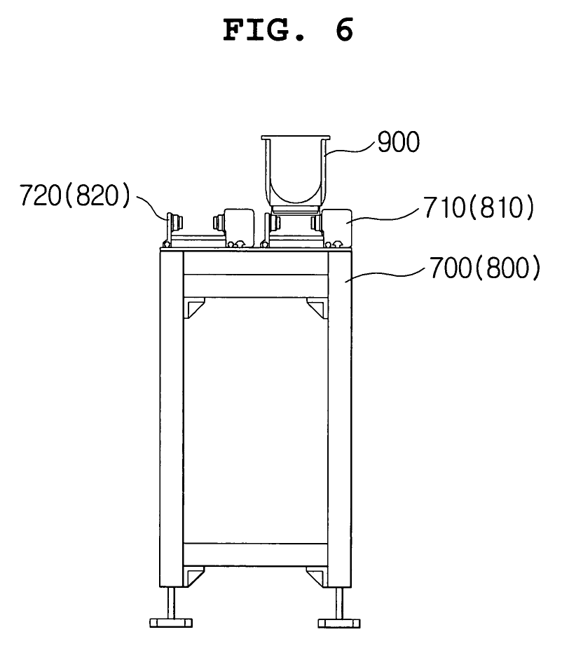

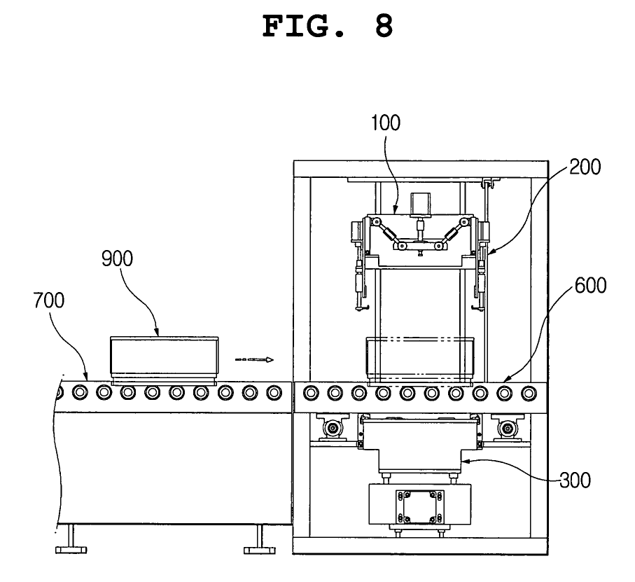

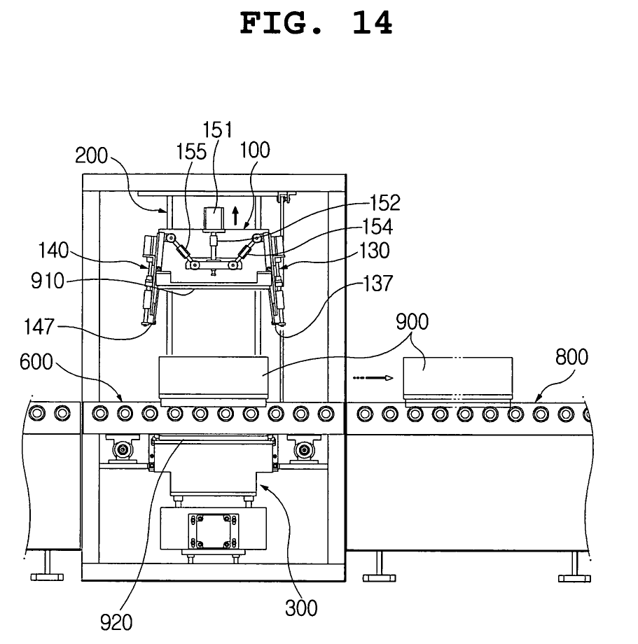

FIG. 1 shows a main body of the inventive thin-film disc containing cassette cover opening/closing apparatus, which essentially comprises a conveyer means (see FIGS. 4 and 8) for feeding and conveying a cassette, in which plural thin-film discs are contained. Hereinafter, the conveyer means will be referred to as “main conveyor.” Although not shown in FIG. 1, the main conveyer 600 (see FIG. 8) will perform its allocated work in a state in which it is connected with an inlet conveyer means 700 (see FIGS. 6 and 8) connected to an inlet side of the main body 1 of the apparatus, and an outlet conveyer means 800 (see FIGS. 6 and 14), which is connected to an outlet side of the main body 1. The inlet conveyer means and the outlet conveyer means will be described later. Here, various components which form the inventive thin-film disc containing cassette cover opening/closing apparatus, and the connective and operative relationship between them are firstly described.

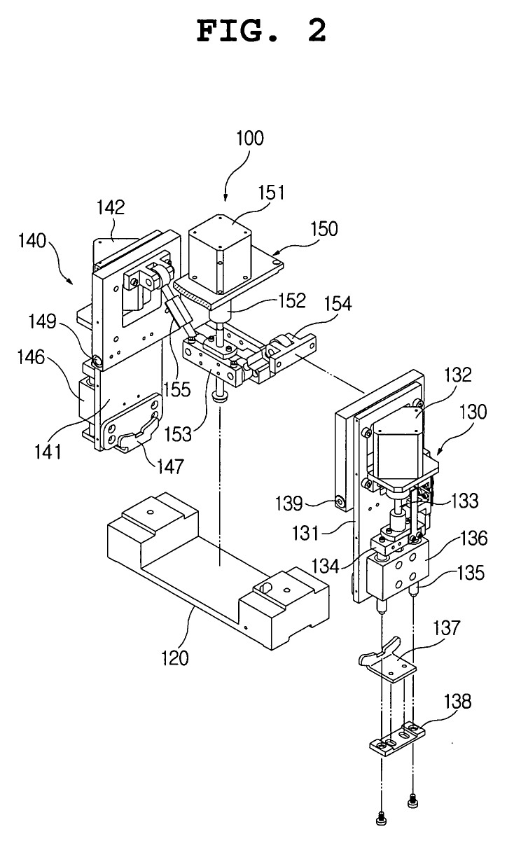

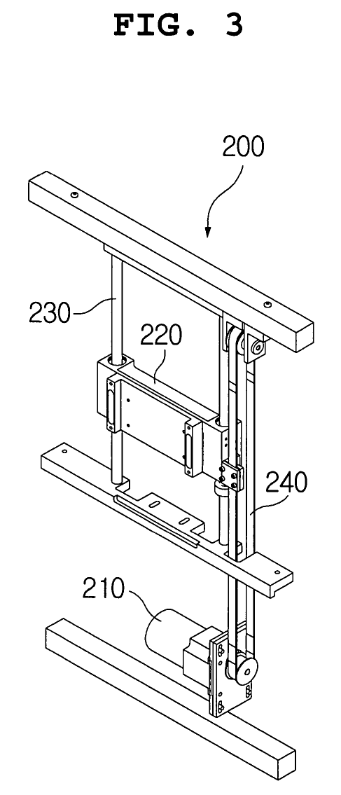

FIGS. 2 to 5 of the accompanying drawings show various components of the main body, in which FIG. 2 is an exploded perspective view showing the components of a top opening/closing means and connective relationship between them in an enlarged scale, and FIG. 3 is a perspective view showing the components of an elevator for raising and lowering the top opening/closing means of FIG. 2 and the connective relationship between them.

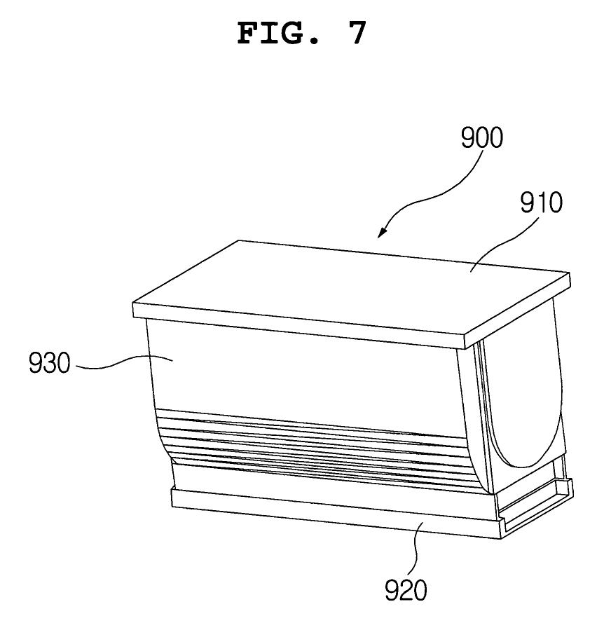

In the present invention, the top opening/closing means 100 serves to open/close the top cover 910 of a cassette 900 (see FIG. 7), in which plural thin-film discs (not shown) are contained, and is arranged in such a manner as to operate on the top of a main conveyer (not shown) within the main body as shown in FIG. 1. Such a top opening/closing means 100 is fitted and secured to the elevator 200, so that it can be moved up and down according to the movement of the elevator 200, which is mounted at the center of the rear side of a main frame 2, which is the bone structure of the main body. The elevator 200 provides raising and lowering movements through an ascending and descending belt 240 (hereinafter, to be referred to as “lifting belt 240”), which is driven by a motor 210, as shown in FIGS. 1 and 3, wherein the elevator 200 comprises a moving holder 220, which is arranged to move along guide bars 230 when it is raised and lowered, the moving holder 220 being connected at one side thereof to the lifting belt 240 for this movement, and the top opening/closing means 100 is engaged with the moving holder 220.

The top opening/closing means 100 comprises a body which corresponds to the base unit of the top opening/closing means, wing units 130 and 140, which are hinged to the opposite ends of the body 120, respectively, in such a manner as to be rotatable in the inward and outward directions, each of the wing units having a gripping means, and a driving unit 150 for controlling the rotating movements of the wing units 130 and 140, wherein the body 120, the wing units 130 and 140, and the driving unit 150 are housed in a single case 110 (see FIG. 1). In the top opening/closing means 110, the driving unit 150 comprises a threaded driving shaft 152 which extends downward from a wing regulating motor 151, which corresponds to a power source for rotating the wing units 130 and 140, an articulated member 153 which is engaged with the driving shaft 152, and joint arms 154 and 155 which connect the opposite sides of the articulated member 153 to the top portions of the wing units 130 and 140, respectively, wherein the opposite ends of each of the joint arms 154 and 155 are rotatably hinged to the wing units 130 and 140 and the articulated member 153.

Meanwhile, the wing units 130 and 140 respectively comprise plate-shaped base members 131 and 141, lifting motors 132 and 142 (hereinafter, to be referred to as “hook regulating motors”) mounted on the outer upper portion of the corresponding base members 131 and 141, threaded lifting shafts 133 and 143 rotatably extending downward from the corresponding hook regulating motors 132 and 142, plural extension bars 135 and 145 extending from corresponding supporting dies 134 and 144, which are fixed to the lower ends of the lifting shafts 133 and 143, respectively, and hooks 137 and 147 adapted to grip the top cover 910 (see FIG. 7) of the thin-film disc containing cassette in a state in which the hooks 137 and 147 are joined and secured to the lower ends of the extension bars 135 and 145. As shown in FIG. 2, the hooks 137, 147 are engaged with and anchored to the lower ends of the extension bars 135 and 145, which extend through the anchoring dies 136 and 146, through suitable anchoring means 138 and 148.

With the top opening/closing means 100 configured in this manner, the rotating direction of the wing units 130 and 140 are changed depending on the driving direction of the wing regulating motor 151, and for this rotation, the wing units 130 and 140 are preferably hinged to the opposite ends of the body 120 through hinge members 139 and 149, respectively.

In operating the top opening/closing means 100, if the driving shaft 152 is rotated in the descending direction by the wing regulating motor 151, the upper portions of the wing units 130 and 140 are drawn by the joint arms 154 and 155 and the lower portions of the wing units 130 and 140 are open from the body 120. On the contrary, if the driving shaft 152 is rotated in the ascending direction by the wing regulating motor 151, the upper portions of the wing units 130 and 140 are pushed outwardly and the lower portions are returned to the original state toward the body 120.

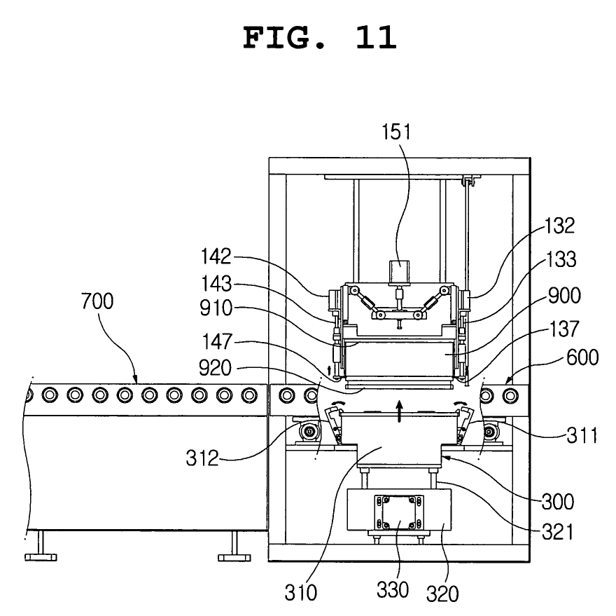

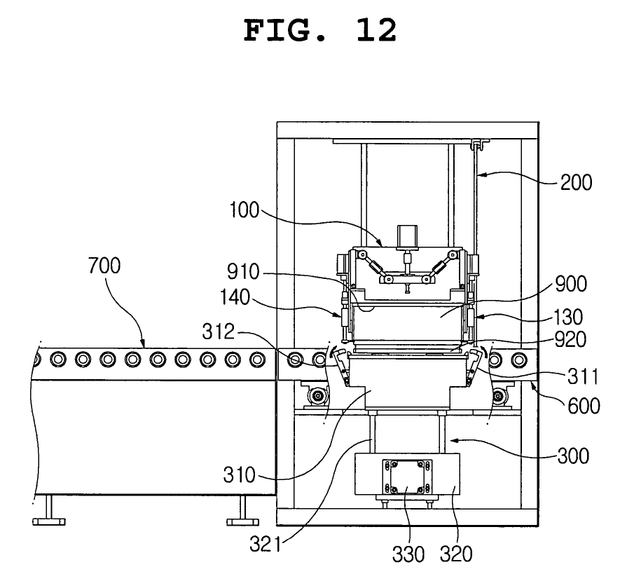

The gripping of the top cover 910 (see FIG. 7) of the thin-film disc containing cassette is initiated as the hook regulating motors 132 and 142 are driven, wherein if the lifting shafts 133 and 143 are rotated in the descending direction by the hook regulating motors 132 and 142, the supporting dies 134 and 144 descend together with the extension bars 135 and 145 and the hooks 137 and 147, and if the lifting shafts are rotated in the ascending direction by the hook regulating motors 132 and 142, the supporting dies 134 and 144 ascend together with the extension bars 135 and 145 and the hooks 137 and 147. During this process, the wing units 130 and 140, in particular the hooks 137 and 147 could grip the top cover of the cassette. This operation will be described in more detail with reference to FIGS. 8 to 14.

FIG. 4 shows connective relationship between a bottom opening/closing means and a conveyer regulating means. As can be seen from the drawing, the bottom opening/closing means 300 is located under the main conveyer 600 (see FIG. 8), and the conveyer regulating means 400 is interposed between the main conveyer 600 and the bottom opening/closing means 300. The conveyer regulating means 400 serves to regulate the width of the main conveyer 600 depending on the size of a cassette as being fed into a predetermined process, and the main conveyer 600 is positioned on the top of the conveyer regulating means 400. The conveyer regulating means 400 is configured in a plate shape, and provided with actuating shafts 420 (hereinafter, to be referred to as “first actuating shaft”) and 430 (hereinafter, to be referred to as “second actuating shaft”) at the longitudinal ends of the plate 410, which are interconnected by plural belts 412 (hereinafter, to be referred to as “linking belt”) and 413 (hereinafter, to be referred to as “driving belt”), so that the first and second actuating shafts 420 and 430 are actuated in cooperation with a motor 440.

In addition, as shown in the drawing, the driving belt 413 interconnects a motor pulley 441 and a first actuating shaft pulley 422, and the linking belt 412 interconnects the first actuating shaft pulley 422 and a second actuating pulley 432, whereby the first actuating shaft 420 and the second actuating shaft 430 are rotated as the motor 440 is driven. At this time, the first actuating shaft 420 and the second actuating shaft 430 are provided with mounting dies 423 and 424 and mounting dies 433 and 434 at the opposite sides thereof with reference to the central portions 421 and 431, respectively, and the main conveyer 600 is adapted to be mounted on the mounting dies 423, 424; 433, 434, wherein it is preferable that the threads (not shown) formed on the first actuating shaft 420 and the threads (not shown) formed on the second actuating shaft 430 are provided in a symmetric form with each other. Meanwhile, the main conveyer 600 interconnects the mounting dies 423 and 434 and the mounting dies 424, 433, which are positioned opposite to one another in the longitudinal direction of the plate 410, wherein the mounting dies 423 and 434 and the mounting dies 424 and 434 are adapted to be moved axially inward or outward, i.e., in the widthwise direction of the plate 410 depending on the rotating directions of the first and second actuating shafts 420 and 430, thereby regulating the width of the main conveyer 600.

The conveyer regulating means 400 has a through-hole 411 with a predetermined size, which is formed in the plate 410, and a head unit 310 of the bottom opening/closing means passes through the through-hole 411 while ascending and descending. The bottom opening/closing means 300 comprises a base unit 320, which includes a motor 330 on a base plate 301, and the head unit 310, which is mounted to be capable of ascending and descending above the base unit 320. The head unit 310 is raised or lowered by a lift arm 322, which is provided under the head unit 310, and the ascending and descending movement of the head unit 310 is effected in vertically up or down along guides 321, which are provided below the head unit 310. The lift arm 322 and the guides 321 are all positioned in the base unit 320.

The head unit 310 is a part which in fact corresponds to the bottom cover 920 (see FIG. 7) of the thin-film disc containing cassette, wherein the head unit 310 is provided at the opposite sides thereof with fingers 311 and 312, which are adapted to grip the opposite ends of the bottom cover 920 so as to open/close the bottom cover 920. These fingers 311 and 312 may grip the bottom cover 920 as being latched to or inserted into corresponding parts formed at the opposite ends of the bottom cover 920. For this purpose, the lower ends of the respective fingers 311 and 312 are rotatably hinged to the head unit 310 (hinge member 310a), and the upper parts of the fingers are repeatedly opened/closed by forward and backward movement of a push arm 310b, which interconnects the fingers 311 and 312, thereby gripping or releasing the bottom cover.

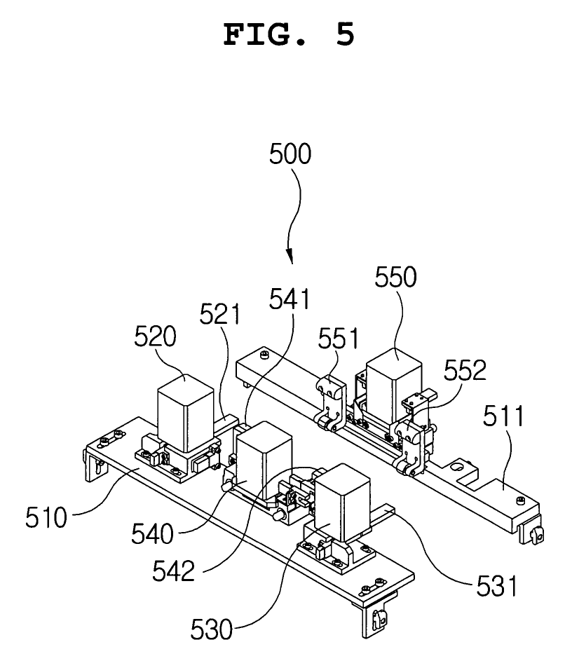

FIG. 5 shows components of a cassette anchoring means installed within the main body of FIG. 1 and connective relationship between them. The cassette anchoring means 500 is positioned between the top opening/closing means 100 and the conveyer regulating means 400, preferably, between the top opening/closing means 100 and the main conveyer 600, as shown in FIG. 1, wherein the cassette anchoring means 500 consists of two anchoring units 510 (hereinafter, to be referred to as “first anchoring unit”) and 511 (hereinafter, to be referred to as “second anchoring unit”) which are opposite to each other in the widthwise direction so as to support two lateral sides of the cassette 900 (see FIGS. 7 and 8) which is fed through the main conveyer 600. The anchoring units 510 and 511 may be fixedly mounted on the main frame 2 as shown in FIG. 1, wherein the first anchoring unit 510 is provided with plural stoppers 521 and 531 for sensing and stopping the cassette depending on the entering direction of the cassette. These stoppers 521 and 531 move perpendicularly to the proceeding direction of the cassette (not shown) on the first anchoring unit, wherein the movement of the stoppers 521 and 531 are controlled by actuating means 520 and 530, which are positioned on the first anchoring unit. In addition, plural grippers 541, 542; 551, 552 are provided on the first anchoring unit 510 and the second anchoring unit 520 so as to prevent the shaking of the cassette, which may be caused while the covers of the cassette are opened and/or closed. These grippers 541, 542; 551, 552 are oppositely positioned so that the lateral and bottom parts of the cassette can be concurrently supported, wherein the grippers 541, 542; 551, 552 may be hinged to the first anchoring unit 510 and the second anchoring unit 511 in such a manner as to be capable of rotating inwardly toward the cassette. In that event, the movements of the grippers 541, 542; 551, 552 are controlled by the actuating means 540 and 550 which are positioned on the first anchoring unit 510 and the second anchoring unit 511, respectively. Meanwhile, the parts of the grippers 541, 542; 551, 552 to be contacted with the cassette are formed from a material, which is as soft as possible, so as to prevent the friction with the cassette and the occurrence of contaminant due to the damage caused by the friction.

FIG. 6 shows inlet conveyer means and outlet conveyer means which are connected to the inlet and outlet of the inventive cassette cover opening/closing apparatus, respectively, by way of an example. As shown in FIG. 6, the inlet conveyer means 700 and the outlet conveyer means 800 may be identically configured, and load conveyers 710 and 820 for feeding the cassette 900 toward the main body 1 (see FIG. 1) and unload cassettes 720, 810 for conveying the cassette 900 discharged from the main body 1 may be provided on the inlet conveyer means 700 and the outlet conveyer means 800, respectively.

FIG. 7 schematically shows an example of a thin-film disc containing cassette which can be used in the inventive cassette cover opening/closing apparatus. The cassette 900 may contain plural thin-film discs and a top cover and a bottom cover are put on the top and the bottom of the cassette, respectively, in such a manner to be capable of being opened. In the drawing, reference numeral “930” denotes the main body of the cassette.

FIGS. 8 to 14 show the operation of the inventive thin-film disc containing cassette opening/closing apparatus. In particular, FIGS. 8 to 14 sequentially show the process for opening the top and bottom covers while the cassette containing plural thin-film discs are passing through the inventive apparatus.

At first, as shown in FIG. 8, the cassette 900 (see FIG. 7) containing plural thin-film discs is fed through the inlet conveyer means 700 which is connected to the inlet side of the inventive opening/closing apparatus, and the cassette 900 fed in this manner is transferred along the main conveyer 600 and then stopped within the main body 1 by the stopper 531 (see FIG. 5). At this time, although not shown in the drawing, the cassette 900 is safely supported by the grippers 541, 551; 542, 552 which are mounted on the anchoring units 510 and 511, of the cassette anchoring means 500, respectively.

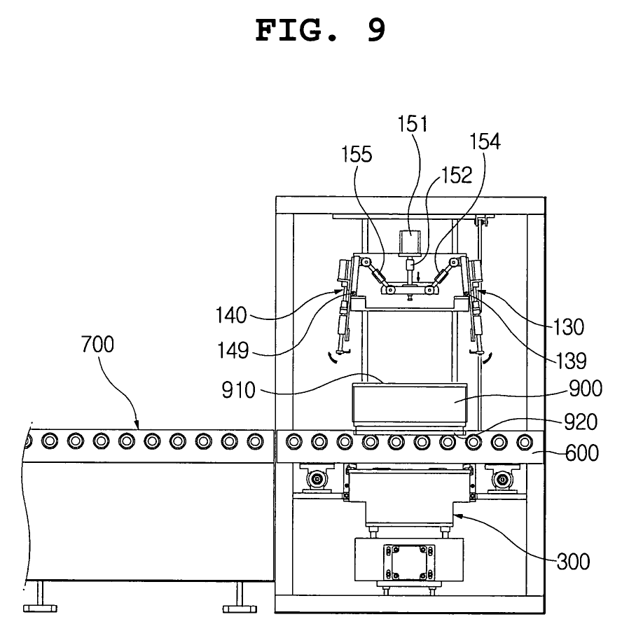

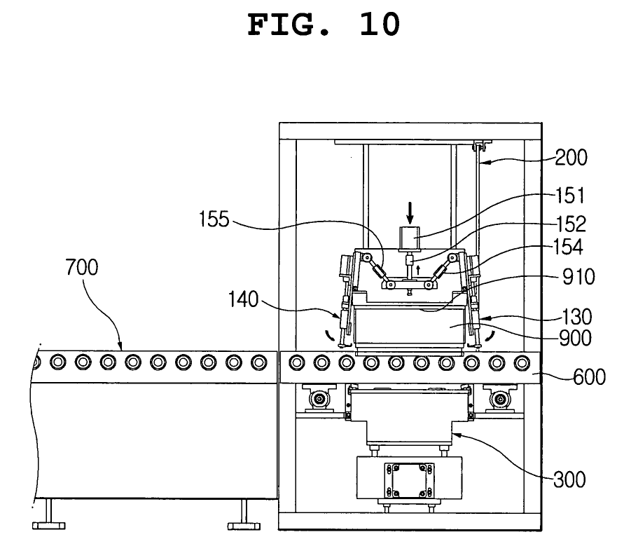

Thereafter, as shown in FIG. 9, as the driving shaft 152 is rotated in the descending direction by the wing regulating motor 511, the articulated member 153 descends, whereby the joint arms 154 and 155 are inwardly drawn, so that the lower ends of the wing units 130 and 140 are outwardly opened about the hinge members 139 and 149. Next, as shown in FIG. 10, as the motor 210 (see FIG. 3) of the elevator 200 is driven, the top opening/closing means 100 descends along the lifting belt 240, whereby the hooks 137 and 147 at the lower ends of the wing units 130 and 140 are positioned under the opposite sides of the cassette 900, and at the same time, the driving shaft 152 is rotated in the ascending direction, thereby raising the articulated member 153. At this time, the joint arms 154 and 155 are outwardly pushed, whereby the lower ends of the wing units 130 and 140 are inwardly rotated about the hinge members 139 and 149. Thereafter, as the hook regulating motors 132 and 142 are driven, thereby rotating the lifting shafts 133 and 143 in the ascending direction, the hooks 137 and 147 grip the top cover 910 of the cassette 900 in the state of being latched to the lower ends of the opposite sides of the top cover 910.

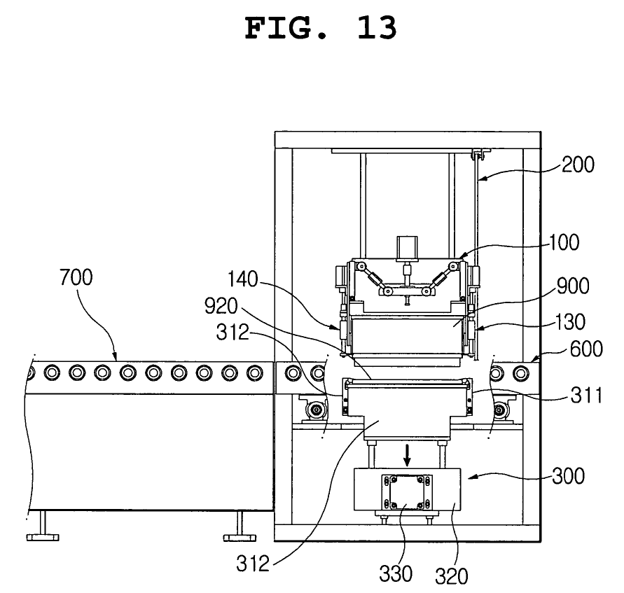

Although not shown in the drawing, in this state, the main conveyer 600 is outwardly widened by the conveyer regulating means 400 (see FIG. 4) and as the motor 330 is driven, the head unit 310 of the bottom opening/closing means 300 is raised through the through-hole 411 formed in the plate 410. At this time, the fingers 311 and 312, which are provided on the opposite sides of the head unit 310, are moved away from each other at the upper parts thereof by the action of the push arm 310b and after the head unit 310 is completely raised, the upper parts of the fingers 311 and 312 are moved toward one another, thereby being latched to and griping the bottom cover 920 of the cassette 900. Thereafter, as the motor 330 is driven, the head unit 30 is lowered as shown in FIG. 13, and at the same time, the bottom cover 920 is removed from the cassette 900. Next, the widened main conveyer 600 is returned to its original condition by the conveyor regulating means, and as the elevator is operated, the top opening/closing means 10 is raised along the lifting belt 240 (see FIG. 3) as shown in FIG. 14. At this time, the top cover 910 is removed from the cassette 900. As the main conveyor 600 is operated, the cassette 900, from which the top and bottom have been removed, is discharged from the inventive cassette cover opening/closing apparatus and then moved to the next process (test process) through the outlet conveyer means 800.

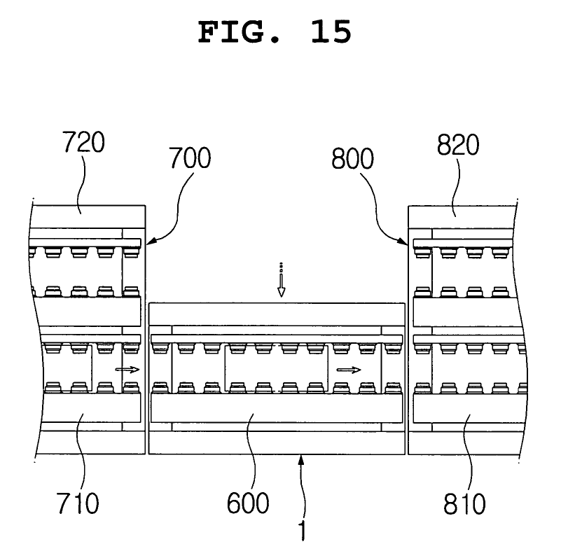

FIG. 15 shows the position of the main conveyer, i.e., the connective relationship between the main conveyer and the inlet and outlet conveyer means, during the process of opening the cassette covers as shown in FIGS. 8 to 14. Although not shown in the drawing, it is preferable if the inventive thin-film cassette cover opening/closing apparatus is configured to be slidably movable forward and backward. If so, the main conveyer 600 is arranged in line with the load conveyer 710 of the inlet conveyer means 700 and the unload conveyer 810 of the outlet conveyer means 800 in the steps of opening the top and bottom covers 910 and 920 of the cassette 900 due to the movement of the inventive apparatus.

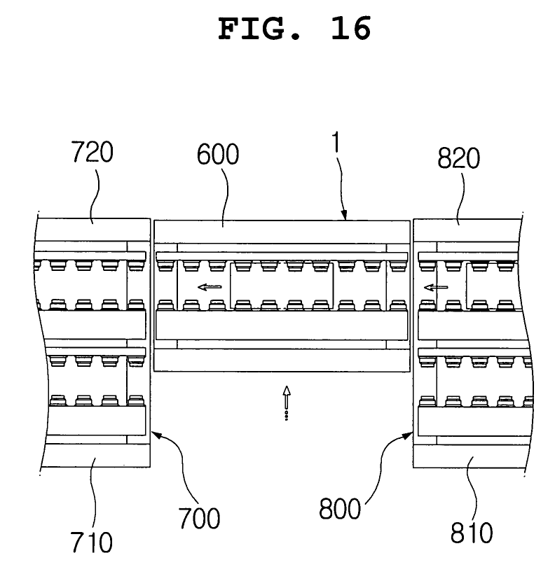

FIG. 16 shows the position of the main conveyer, i.e., the connective relationship between the inlet and outlet conveyer means and the main conveyer in the steps of closing the cassette covers, which are reversely performed as compared with the steps of opening the cassette covers. Although not shown in the drawing, the cassette 900 is fed through the outlet conveyer means 800 during the process of closing the covers of the cassette 900, and discharged to the outside through the inlet conveyer means 700 after the various operations in the inventive cassette cover closing steps are completed, on the contrary of the above-mentioned cover opening process. For this purpose, during the process of closing the cassette covers, the main conveyer 600 is arranged in line with the unload conveyer 720 of the inlet conveyer means 700 and the load conveyer 810 of the outlet conveyer means 800 through the sliding movement of the inventive apparatus. Meanwhile, according to the present invention, the process of closing the covers of the cassette is performed in the same sequence as the process shown in FIGS. 8 to 14 except the feeding and discharge directions of the cassette.

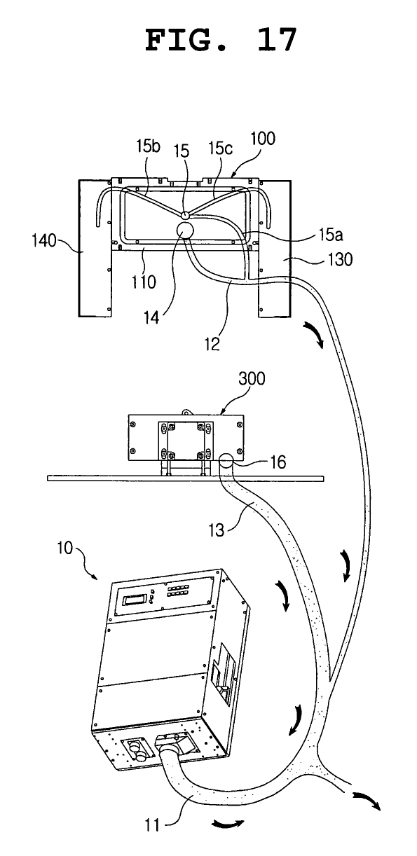

FIG. 17 shows schematic arrangement of air intake means installed various parts of the inventive cassette cover opening/closing apparatus and the connective relationship thereof. The inventive cassette cover opening/closing apparatus may be provided with one or more air intake means so as to remove a contaminant such as dust which may be generated while the inventive apparatus operates. As an example of such air intake means, a first air intake tube 14 is installed in the case 110 of the top opening/closing means 100 so as to suction a contaminant produced within the case 110, as shown in FIG. 17.

In addition, so as to suction a contaminant produced from the wing units 130 and 140, a second air intake tube 15 is installed in the top opening/closing means 100, and the branch tubes 15b and 15c of the second air intake tube 15 are connected with the wing units 130 and 140, respectively, and in order to remove a contaminant produced from the bottom opening/closing means 300, a third air intake tube 16 is installed in the bottom opening/closing means 300.

Meanwhile, the contaminants, which are produced in various parts of the inventive apparatus and suctioned through the first, second and third air intake tubes 14, 15 and 16 flow along pipes 12, 15a, 13 extending from the tubes 14, 15 and 16, whereby the contaminants meet wind, which is blown through a discharge pipe 11 of air discharge means, and then the contaminants are discharged to the outside together by the wind.

In this way, the inventive apparatus can be very safely operated even in a space which requires super cleanliness, at least in the level of class 10, like a thin-film disc test.

As described above, the inventive thin-film disc containing cassette cover opening/closing apparatus can open or close the top and bottom covers of a cassette without producing a contaminant in a test process for thin-film discs, thereby assuring the quality and safety of articles.

In addition, the inventive thin-film disc containing cassette cover opening/closing apparatus allows the cassette cover opening/closing operation to be more smoothly performed without requiring a complete change in the apparatus even if the sizes of cassettes fed into a predetermined process are varied because each working unit is capable of being flexibly operated in accordance with the sizes of individual cassettes.

Although a preferred embodiment of the present invention has been described for illustrative purposes, those skilled in the art will appreciate that various modifications, additions and substitutions are possible, without departing from the scope and spirit of the invention as disclosed in the accompanying claims.

What is claimed is:

1. An apparatus for opening/closing a cover of a thin-film disc containing cassette comprising:
a main conveyer for feeding and conveying a cassette, in which plural thin-film discs are contained;
top opening/closing means positioned above the main conveyer so as to open/close a top cover of the cassette;
an elevator for inducing vertical movement of the top opening/closing means;
a bottom opening/closing means positioned below the main conveyer so as to open/close a bottom cover of the cassette, of which a portion is capable of being moved up and down depending on the movement of a motor;
a conveyer regulating means for regulating the width of the main conveyer according to the size of the cassette, the main conveyer being supported on the conveyer regulating means; and
a cassette anchoring means for supporting and anchoring the cassette transferred to a main body of the apparatus through the main conveyer.

2. An apparatus as claimed in claim 1, wherein the main conveyer is connected to an inlet conveyer means and an outlet conveyer means, the inlet conveyer means being connected to an inlet end of the main body and the outlet conveyer means being connected to an outlet end of the outlet conveyer means, wherein the conveyer regulating means is interposed between the main conveyer and the bottom opening/closing means, and wherein the cassette anchoring means is interposed between the top opening/closing means and the main conveyer.

3. An apparatus as claimed in claim 1, wherein the top opening/closing means is fitted and secured to the elevator so that the top opening/closing means is capable of being moved up and down depending on the movement of the elevator,
wherein the elevator is installed at the center of the rear end of a main frame, which is the bone structure of the main body, and guides the ascent and descent of the top opening/closing means through a lifting belt, which is driven by a motor, and
wherein the elevator comprises a moving holder, to which the top opening/closing means is engaged, one or more guide bars for guiding the ascent and descent of the moving holder, and the lifting belt connected to a side of the moving holder so as to transmit the power of the motor for the ascent and descent of the moving holder.

4. An apparatus as claimed in claim 1, wherein the top opening/closing means comprises:
a body which corresponds to the base unit of the top opening/closing means;
wing units, which are hinged to the opposite ends of the body, respectively, in such a manner as to be rotatable in the inward and outward directions, each of the wing units having a gripping means; and
a driving unit for controlling the rotating movements of the wing units, wherein the driving unit comprises:
a threaded driving shaft which extends downward from a wing regulating motor, which corresponds to a power source for rotating the wing units,
an articulated member which is mated with the driving shaft, and
joint arms, which connect the opposite sides of the articulated member to the top portions of the wing units, respectively, the opposite ends of each of the joint arms being rotatably hinged to the wing units and the articulated member.

5. An apparatus as claimed in claim 4, wherein each of the wing unit comprises:
a plate-shaped base member;
a hook regulating motor mounted on the outer upper portion of the base member;
a threaded lifting shaft rotatably extending downward from the hook regulating motor;
plural extension bars extending from a supporting die, wherein the supporting die is fixed to the lower end of the lifting shaft; and
a hook adapted to grip the top cover of the thin-film disc containing cassette in a state in which the hook is engaged with and secured to the lower end of the extension bar.

6. An apparatus as claimed in claim 4, wherein the wing units are hinged to the opposite ends of the body through hinge members, respectively, in such a manner that the rotating directions of the wing units are changed depending on the driving direction of the wing regulating motor.

7. An apparatus as claimed in claim 1, wherein The conveyer regulating means is configured in a plate shape, and provided with first and second actuating shafts at the longitudinal ends of the plate, which are interconnected by a linking belt and a driving belt, so that the first and second actuating shafts are actuated in cooperation with a motor.

8. An apparatus as claimed in claim 7, wherein the driving belt interconnects a motor pulley and a first actuating shaft pulley, and the linking belt interconnects the first actuating shaft pulley and a second actuating pulley, whereby the first actuating shaft and the second actuating shaft are rotated as the motor is driven, and
wherein the first actuating shaft and the second actuating shaft are provided with mounting dies at the opposite sides thereof with reference to the central portions thereof, respectively, the main conveyer being mounted on the mounting dies.

9. An apparatus as claimed in claim 8, wherein the main conveyer interconnects the mounting dies, which are opposite to one another in the longitudinal direction of the plate, and
wherein the threads formed on the first actuating shaft and the threads formed on the second actuating shaft 430 are provided in a symmetric form with each other, so that the mounting dies are adapted to be moved axially inward or outward depending on the rotating directions of the first and second actuating shafts, thereby regulating the width of the main conveyer.

10. An apparatus as claimed in claim 1, wherein the conveyer regulating means has a through-hole with a predetermined size, which is formed in the plate, and a head unit of the bottom opening/closing means passes through the through-hole while ascending and descending.

11. An apparatus as claimed in claim 1, wherein the bottom opening/closing means comprises:
a base unit, which includes a motor on a base plate; and
a head unit, which is mounted to be capable of ascending and descending above the base unit, the head unit being raised or lowered by a lift arm, which is provided under the head unit, and the ascending and descending movement of the head unit being effected in the vertical direction along guides, which are provided below the head unit.

12. An apparatus as claimed in claim 11, wherein the head unit is provided, at the opposite sides thereof, with fingers, which are adapted to grip the opposite ends of the bottom cover in a state of being latched to or inserted into corresponding parts of the bottom cover, which are formed at the opposite ends of the bottom cover, the lower ends of the respective fingers being rotatably hinged to the head unit, and the upper parts of the fingers being repeatedly opened/closed by forward and backward movements of a push arm, which interconnects the fingers, thereby gripping or releasing the bottom cover.

13. An apparatus as claimed in claim 1, wherein the cassette anchoring means consists of first and second anchoring units, which are opposite to each other in the widthwise direction so as to support the opposite sides of the cassette which is fed through the main conveyer,
wherein the first anchoring unit is provided with plural stoppers for sensing and stopping the cassette depending on the entering direction of the cassette, and
wherein the stoppers move perpendicularly to the proceeding direction of the cassette on the first anchoring unit, the movements of the stoppers being controlled by actuating means, which are positioned on the first anchoring unit.

14. An apparatus as claimed in claim 13, wherein plural grippers are provided on the first anchoring unit and the second anchoring unit so as to prevent the shaking of the cassette, which may be caused while the covers of the cassette are opened and/or closed, the grippers being oppositely positioned so that the lateral and bottom parts of the cassette can be concurrently supported, and
wherein the grippers are hinged to the first anchoring unit and the second anchoring unit in such a manner as to be capable of rotating inwardly toward the cassette, and the movements of the grippers are controlled by the actuating means which are positioned on the first anchoring unit and the second anchoring unit, respectively.

15. An apparatus as claimed in claim 2, wherein the inlet conveyer means and the outlet conveyer means are identically configured, and one or more load conveyers for feeding the cassette toward the main body and one or more unload cassettes conveying the cassette discharged from the main body are provided on the inlet conveyer means and the outlet conveyer means, respectively.

16. An apparatus as claimed in claim 15, wherein the apparatus is configured to be slidably movable forward and backward, wherein the main conveyer is arranged in line with the load conveyer of the inlet conveyer means and the unload conveyer of the outlet conveyer means in the steps of opening the top and bottom covers of the cassette due to the movement of the apparatus.

17. An apparatus as claimed in claim 15, wherein the apparatus is configured to be slidably movable forward and backward, wherein the cassette is fed through the outlet conveyer means during the process of closing the top and bottom covers of the cassette, and discharged to the outside through the inlet conveyer means after the closing operations are completed.

18. An apparatus as claimed in claim 16 or 17, wherein during the process of closing the cassette covers, the main conveyer is arranged in line with the unload conveyer of the inlet conveyer means and the load conveyer of the outlet conveyer means through the sliding movement of the apparatus.

19. An apparatus as claimed in claim 4, further comprising one or more air intake means so as to remove a contaminant such as dust which may be generated while the inventive apparatus operates, wherein the air intake means comprises:
a first air intake tube, which is installed in the case of the top opening/closing means so as to suction a contaminant produced within the case,
a second air intake tube, which is installed in the top opening/closing means so as to suction a contaminant produced from the wing units, the second intake tube having branch tubes, which are connected with the wing units, respectively, and
a third air intake tube is installed in the bottom opening/closing means so as to remove a contaminant produced from the bottom opening/closing means, wherein the contaminants, which are produced in various parts of the inventive apparatus and suctioned through the first, second and third air intake tubes, flow along pipes extending from the first, second and third air intake tubes, whereby the contaminants are adapted to be discharged to the outside together with the wind, which is blown through a discharge pipe of air discharge means.
